(19) United States
(12) Patent Application Publication
(10) Pub. No.: US 2025/0311277 A1
(43) Pub. Date: Oct. 2, 2025

(54) SEMICONDUCTOR STRUCTURE

(71) Applicant: TAIWAN SEMICONDUCTOR MANUFACTURING COMPANY LTD., HSINCHU (TW)

(72) Inventors: CHI-MING CHEN, HSINCHU COUNTY (TW); KUEI-MING CHEN, NEW TAIPEI CITY (TW); CHUNG-YI YU, HSINCHU CITY (TW)

(21) Appl. No.: 19/238,573

(22) Filed: Jun. 16, 2025

Related U.S. Application Data
(62) Division of application No. 17/810,857, filed on Jul. 6, 2022.
Application No. 17/810,857 is a division of application No. 15/938,386, filed on Mar. 28, 2018, now abandoned.

(51) Int. Cl. H10D 30/47; H10D 62/824; H10D 62/85; H10D 62/854

(52) U.S. Cl. CPC H10D 30/4755; H10D 62/824; H10D 62/8503; H10D 62/854

(57) ABSTRACT

A semiconductor structure includes a p-type doped III-V compound layer, a channel layer disposed over the p-type doped III-V compound layer, and a barrier structure. The channel layer includes an upper portion and a lower portion. The barrier structure is disposed between the upper portion of the channel layer and the lower portion of the channel layer. The barrier structure includes a first barrier layer, a second barrier layer and a third barrier layer. The first barrier layer is disposed between the second barrier layer and the third barrier layer. The channel layer has a first band gap, the first barrier layer has a second band gap, and the second barrier layer has a third band gap. The second band gap and the third band gap are greater than the first band gap.

### PRIORITY DATA

This patent is a divisional application of U.S. patent application Ser. No. 17/810,857, filed on Jul. 6, 2022, entitled of “SEMICONDUCTOR STRUCTURE”, which is a divisional application of U.S. patent application Ser. No. 15/938,386 filed on Mar. 28, 2018, entitled of “SEMICONDUCTOR STRUCTURE”, the entire disclosure of which is hereby incorporated by reference.

### BACKGROUND

In the semiconductor technology, due to their characteristics, group III-V semiconductor compounds are used to form various integrated circuit devices, such as high power field-effect transistors, high frequency transistors, or high electron mobility transistors (HEMTs). A HEMT is a field effect transistor incorporating a junction between two materials with different band gaps (i.e., a heterojunction) as the channel instead of a doped region, as is generally the case for metal oxide semiconductor field effect transistors (MOSFET). In contrast with MOSFETs, HEMTs have a number of attractive properties including high electron mobility and the ability to transmit signals at high frequencies, etc.

From an application point of view, HEMTs have many advantages. Despite the attractive properties mentioned above, a number of challenges exist in connection with developing III-V semiconductor compound-based devices. Various techniques directed at configurations and materials of these III-V semiconductor compounds have been implemented to try and further improve transistor device performance.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic drawing illustrating a HEMT device according to aspects of the present disclosure in some embodiments.

FIG. 2 is a schematic drawing illustrating a HEMT device according to aspects of the present disclosure in some embodiments.

FIG. 3A is a schematic drawing illustrating a semiconductor structure for the HEMT device in accordance with embodiments of the present disclosure.

FIG. 3B is a schematic drawing illustrating a semiconductor structure for the HEMT device in operation in accordance with embodiments of the present disclosure.

FIG. 3C is a diagram of a HEMT device including the semiconductor structure having the barrier layer and a HEMT device without the barrier layer in accordance with embodiments of the present disclosure.

FIG. 4A is a schematic drawing illustrating a semiconductor structure for the HEMT device in accordance with embodiments of the present disclosure.

FIG. 4B is a schematic drawing illustrating a semiconductor structure for the HEMT device in operation in accordance with embodiments of the present disclosure.

FIG. 5A is a schematic drawing illustrating a semiconductor structure for the HEMT device in accordance with embodiments of the present disclosure.

FIG. 5B is a schematic drawing illustrating a semiconductor structure for the HEMT device in operation in accordance with embodiments of the present disclosure.

FIG. 6A is a schematic drawing illustrating a semiconductor structure for the HEMT device in accordance with embodiments of the present disclosure.

FIG. 6B is a schematic drawing illustrating a semiconductor structure for the HEMT device in operation in accordance with embodiments of the present disclosure.

FIG. 7A is a schematic drawing illustrating a semiconductor structure for the HEMT device in accordance with embodiments of the present disclosure.

FIG. 7B is a schematic drawing illustrating a semiconductor structure for the HEMT device in operation in accordance with embodiments of the present disclosure.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper”, “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the terms such as “first”, “second” and “third” describe various elements, components, regions, layers and/or sections, these elements, components, regions, layers and/or sections should not be limited by these terms. These terms may be only used to distinguish one element, component, region, layer or section from another. The terms such as “first”, “second” and “third” when used herein do not imply a sequence or order unless clearly indicated by the context.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, two numerical values can be deemed to be “substantially” the same or equal if a difference between the values is less than or equal to ±10% of an average of the values, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” parallel can refer to a range of angular variation relative to 0° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Group III-V semiconductor compounds are used to form various integrated circuit devices, such as HEMT device. For example, in some embodiments, gallium nitride on silicon (GaN-on-Si) based devices have become an attractive option for power devices over past years. GaN transistor devices provide for a high electron mobility in a two-dimensional electron gas (2DEG) layer located near the interface of an AlGaN and a GaN heterostructure interface. In other words, the 2DEG layer, instead of a doped region as is generally the case for MOSFET devices, acts as the channel.

Similar to MOSFET devices, HEMT devices include a gate electrode, a source electrode and a drain electrode. As size reduction of HEMT devices proceeds, it has enabled the continued improvement in speed, performance, density, and cost per unit function of integrated circuits over the past few decades. However as sizes are reduced, undesirable effects, such as source punch-through, may be created. In some embodiments, the punch through issue is severer in HEMT devices because its small gate length (Lg), high carrier density in the 2DEG layer and the high electric field at the gate edge.

The present disclosure therefore provides a semiconductor structure including a barrier layer inserted in the GaN channel layer or under the GaN channel layer. In some embodiments, the barrier layer is under the 2DEG layer and includes a band gap greater than the GaN channel layer. Consequently, the punch through effect is mitigated due to the higher electron jump barrier provided by the barrier layer. Accordingly, device performance is improved.

It should be easily realize that the semiconductor structure provided in accordance with some embodiments of the present disclosure can be adopted to a HEMT device, but not limited thereto. In some embodiments, the semiconductor structure can be used in various IC devices such as high power device, field-effect transistor (FET) device, light-emitting diode (LED) device, high-frequency device, or other suitable IC devices.

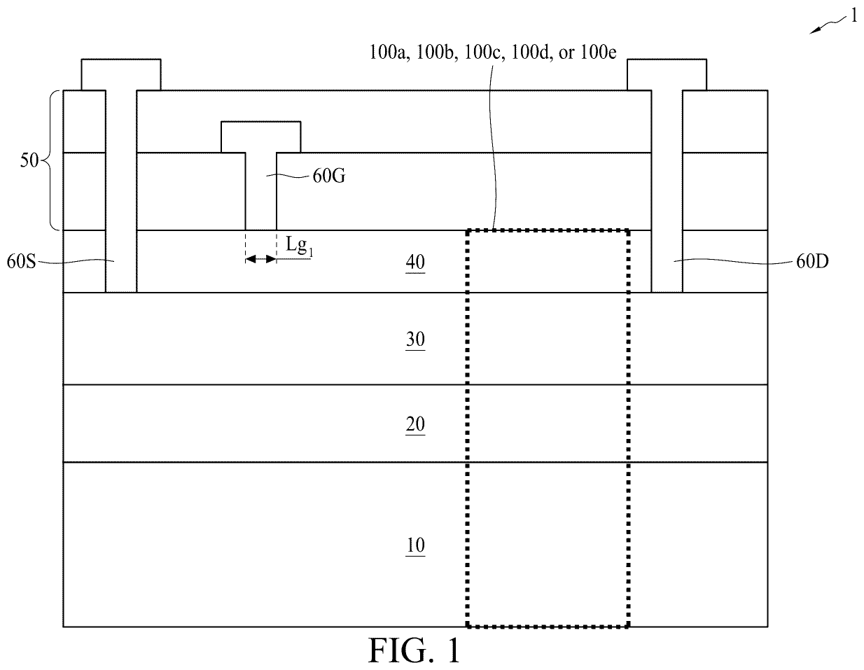

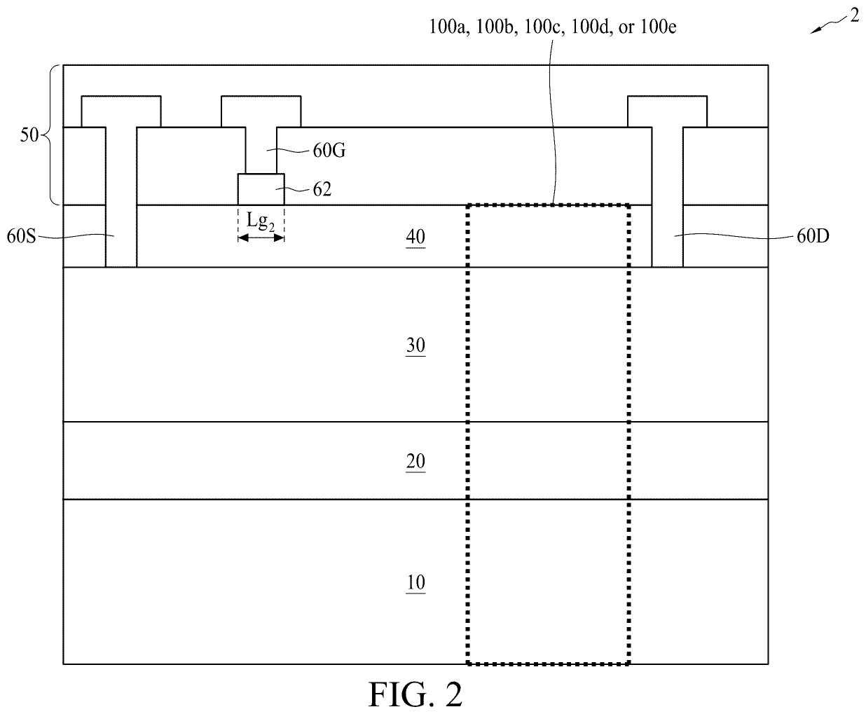

FIGS. 1 and 2 are schematic drawings respectively illustrating a HEMT device 1 and a HEMT device 2 according to aspects of the present disclosure in some embodiments. In some embodiments, the HEMT device 1 and the HEMT device 2 respectively include a semiconductor structure 100a, 100b, 100c, 100d or 100e. In some embodiments, the semiconductor structure 100a-100e of the HEMT device 1 and the HEMT device 2 respectively include a substrate 10, a buffer layer 20 disposed over the substrate 10, an III-V compound stack 30 disposed over the buffer layer 20, and an active layer 40 disposed over the III-V compound stack 30. In some embodiments, the HEMT device 1 and the HEMT device 2 respectively include a gate electrode 60G, a source electrode 60S and a drain electrode 60D disposed over the semiconductor structure 100a, 100b, 100c, 100d or 100e. The gate electrode 60G, the source electrode 60S and the drain electrode 60D can include a conductive material such as metal. Contacts such as gate contact, source contact and drain contact can be formed as shown in FIGS. 1 and 2. Further, Ohmic contacts (not shown) can be formed by doping the layers underlying the source electrode 60S and the drain electrode 60D, if required.

As shown in FIGS. 1 and 2, in some embodiments, the source electrode 60S and the drain electrode 60D respectively penetrate into the active layer 40 of the semiconductor structure 100a-100e and contacts the III-V compound stack 30, but the disclosure is not limited thereto. The gate electrode 60G is disposed over the active layer 40 of the semiconductor structure 100a-100e. In some embodiments, a bottom of the gate electrode 60G locates on the active layer 40, and a gate length Lg₁ is defined by a width of the gate electrode 60G, as shown in FIG. 1. A carrier channel of the HEMT device 1 becomes normally-on. In the operation, a negative gate voltage is applied to turn off the carrier channel of the HEMT device 1, and thus the HEMT device 1 is also recognized as a depletion-mode HEMT (also referred to as a D-mode HEMT) device. In some embodiments, a III-V compound layer 62 is disposed between the gate electrode 60G and the active layer 40, and a gate length Lg₂ is defined by a width of the III-V compound layer 62, as shown in FIG. 2. In some embodiments, the III-V compound layer 62 includes a doped III-V compound layer, such as a p-doped GaN layer, but the disclosure is not limited thereto. In some embodiments, the p-doped GaN layer 62 and the underlying active layer 40 form a PN junction. Such PN junction depletes the 2DEG under the gate electrode 60G, when no voltage is applied. A carrier channel of the HEMT device 2 therefore becomes normally-off. In the operation, a positive gate voltage is applied to turn on the carrier channel of the HEMT device 2, and thus the HEMT device 2 is also recognized as an enhanced-mode HEMT (also referred to as an E-mode HEMT) device.

In some embodiments, the substrate 10 of the semiconductor structure 100a-100e includes a silicon carbide (SiC) substrate, sapphire substrate, or a silicon substrate. In at least one embodiments, the substrate 10 includes a (111) silicon wafer. That is, the silicon substrate includes a top surface in a (111) plane, where the (111) is a crystalline plane represented by Miller indexes as known in the art. The (111) silicon wafer is chosen to provide a proper lattice mismatch with an overlying layer, but the disclosure is not limited thereto.

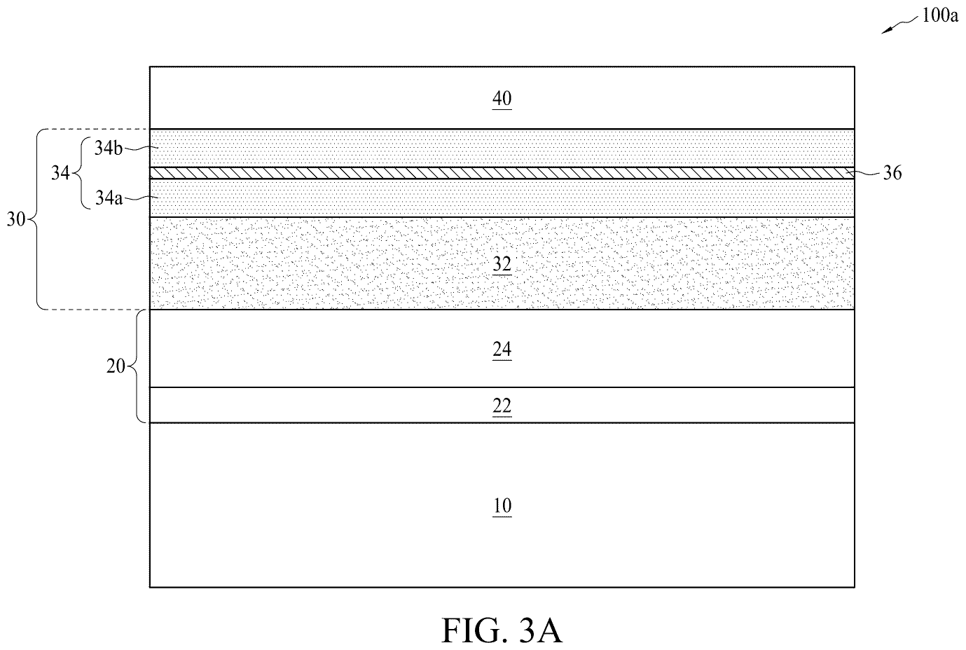

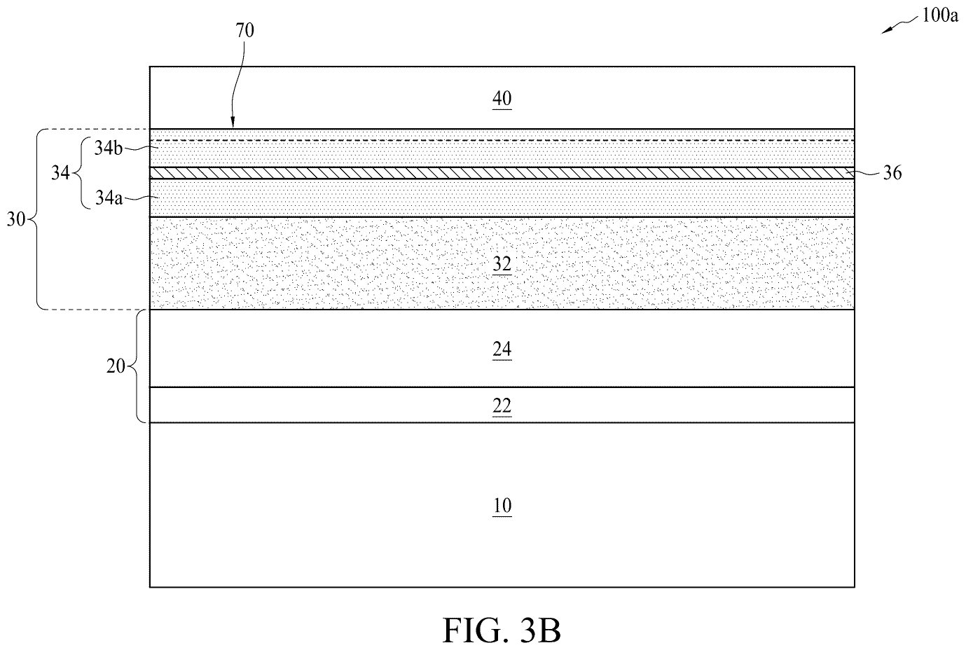

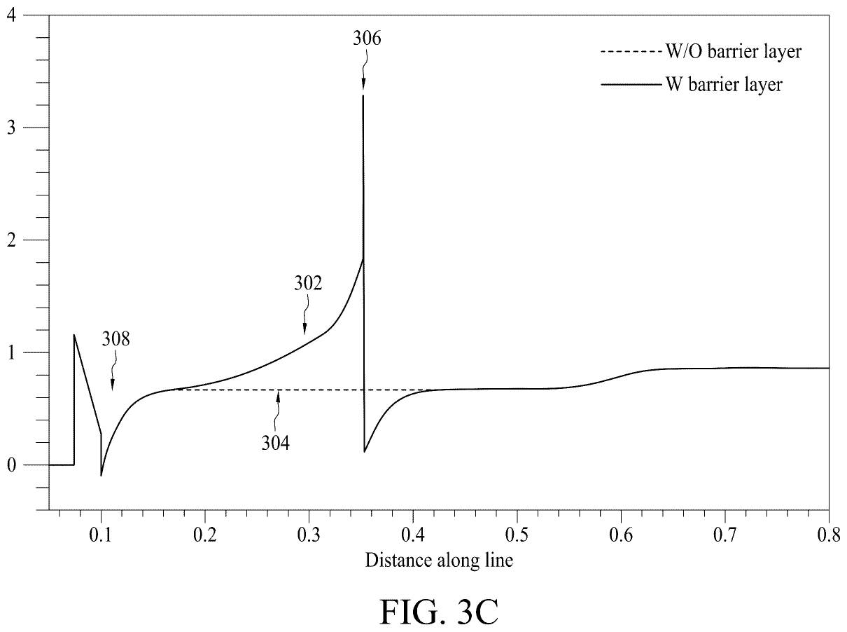

Referring to FIGS. 3A, 4A, 5A, 6A and 7A, the buffer layer 20 of the semiconductor structure 100a-100e can be a multi-layered structure. In some embodiments, the buffer layer 20 includes at least a seed layer 22 and a transition layer 24. In some embodiments, the seed layer 22, also known as a nucleation layer, has a lattice structure and/or a thermal expansion coefficient (TEC) suitable for bridging the lattice mismatch and/or the TEC mismatch between the substrate 10 and an overlying layer, such as the III-V compound stack 30. In some embodiments, the seed layer 22 includes aluminum nitride (AlN), but the disclosure is not limited thereto. In some embodiments, the seed layer 22 is formed by epitaxial growth such as, for example but not limited thereto, a metal-organic chemical vapor deposition (MOCVD), a molecular beam epitaxy (MBE), and a hydride vapor phase epitaxial (HVPE).

The transition layer 24 of the buffer layer 20 of the semiconductor structure 100a-100e is disposed on the seed layer 22. However, in some embodiments the transition layer 24 can be formed over the substrate 10 where the seed layer is omitted. The transition layer 24 further facilitates gradual changes of lattice structures and TECs between the seed layer 22 (or the substrate 10) and the overlying III-V compound stack 30. In some embodiments, the transition layer 24 includes a graded aluminum-gallium nitride (Alₓ₁Ga₍₁₋ₓ₁₎N), and x1 is the aluminum content ratio in the AlGaN layer. In some embodiments, the graded AlGaN layer includes multiple layers each having an Al content ratio x1 decreased from a bottom layer adjoining the seed layer 22 to a top layer adjoining the III-V compound stack 30. In some embodiments, the Al content ratios x1 in individual AlGaN layers are decreased from 1 to 0.1. Numbers of the AlGaN layers and/or the Al content ratios x1 in individual AlGaN layers are within the scope of various embodiments. In some embodiments, instead of having multiple layers with different x1 ratios, the graded AlGaN layer has a continuous gradient of the ratio x1. In some embodiments, the continuous gradient of the ratio x1 is decreased from 1 to 0.1 from a region adjoining the seed layer 22 (or the substrate 10) to a region adjoining the III-V compound stack 30. In some embodiments, the transition layer 24 is formed by an epitaxial growth such as, for example but not limited to, MOCVD. In some embodiments, the transition layer 24 can be omitted.

Referring to FIGS. 3A, 4A, 5A, 6A and 7A, the active layer 40 of the semiconductor structure 100a-100e includes one or more III-V compound layers which may different from the III-V compound stack 30 in composition. In some embodiments, the active layer 40 includes AlN, AlGaN, indium-aluminum nitride (InAlN), aluminum-gallium arsenide (AlGaAs), aluminum-indium phosphide (AlInP), or a combination thereof. In some embodiments, the active layer 40 includes Alₓ₂Ga₍₁₋ₓ₂₎N, where x2 is the Al content ratio, and the Al content ratio x2 ranges from approximately 0.1 to approximately 0.3. In some embodiments, the Al content ratio x2 ranges from approximately 0.13 to approximately 0.15, but the disclosure is not limited thereto. In some embodiments, the active layer 40 includes a thickness ranges from approximately 10 nanometers (nm) to approximately 30 nm, but the disclosure is not limited thereto. In some embodiments, the thickness of the active layer 40 ranges from approximately 15 nm to approximately 25 nm, but the disclosure is not limited thereto. It should be understood that the active layer 40 is used to provide a band gap discontinuity to form a 2DEG layer. Therefore if the active layer 40 is too thick, selectively controlling the conductivity of the channel layer is difficult. However if the active layer 40 is too thin, an insufficient amount of electrons are available to form 2DEG. In some embodiments, the active layer 40 is formed by an epitaxial growth such as, for example but not limited to, MOCVD.

Referring to FIG. 3A, the III-V compound stack 30 of the semiconductor structure 100a is sandwiched between the buffer layer 20 and the active layer 40. The III-V compound stack 30 can includes a first III-V compound layer 32 disposed over the buffer layer 20, a second III-V compound layer 34a disposed over the first III-V compound layer 32, a third III-V compound layer 34b disposed over the second III-V compound layer 34a, and a barrier layer 36 sandwiched between the second III-V compound layer 34a and the third III-V compound layer 34b. The barrier layer 36 is separated from the first III-V compound layer 32 by the second III-V compound layer 34a. Additionally, the active layer 40 is disposed on the third III-V compound layer 34b, as shown in FIG. 3A. The first III-V compound layer 32 includes dopants, such as p-type dopants. In some embodiments, the p-type doped III-V compound layer 32 is provided to trap electrons diffused from the substrate 10 and thus to reduce electron injection from the substrate 10. In some embodiments, the first III-V compound layer 32 includes gallium nitride (GaN) doped with p-type dopants. In some embodiments, the p-type dopants include carbon (C), iron (Fe), magnesium (Mg), Zinc (Zn) or other suitable p-type dopants. In some embodiments, a concentration of the p-type dopants ranges from approximately 5E18 ions/cm³ to approximately 2E19 ions/com³, but the disclosure is not limited thereto. In some embodiments, a thickness of the p-type doped first III-V compound layer 32 ranges from approximately 0.5 micrometer (μm) to approximately 5 μm, but the disclosure is not limited thereto. If the thickness of the p-type doped first III-V compound layer 32 is less than 0.5 μm, it is too thin to be able to prevent electron injection from the substrate 10. In some embodiments, the p-type doped first III-V compound layer 32 is formed by an epitaxial growth such as, for example but not limited to, MOCVD or MBE.

Still referring to FIG. 3A, the second III-V compound layer 34a and the third III-V compound layer 34b include a same material such as an undoped III-V compound layer or an unintentionally doped III-V compound layer. In some embodiments, the second III-V compound layer 34a and the third III-V compound layer 34b include the same material such as an undoped GaN layer or an unintentionally doped GaN layer, but the disclosure is not limited thereto. Accordingly, the second III-V compound layer 34a and the third III-V compound layer 34b can be taken as one III-V compound layer 34 while the second III-V compound layer 34a is referred to as a lower region and the third III-V compound layer 34b is referred to as an upper region of the III-V compound layer 34. The lower region 34a and the upper region 34b of the III-V compound layer 34 include a first band gap. In some embodiments, a thickness of the second III-V compound layer 34a (the lower region 34a) ranges from approximately 0.4 μm to approximately 0.6 μm, but the disclosure is not limited thereto. In some embodiments, a thickness of the third III-V compound layer 34b (the upper region 34b) ranges approximately 0.2 μm to approximately 0.4 μm, but the disclosure is not limited thereto. In some embodiments, the lower region 34a and the upper region 34b of the III-V compound layer 34 respectively are formed by an epitaxial growth such as, for example but not limited to, MOCVD or MBE.

Still referring to FIG. 3A, the barrier layer 36 is sandwiched between the undoped (or unintentionally doped) upper region 34b and the undoped (or unintentionally doped) lower region 34a. Further, the barrier layer 36 is separated from the active layer 40 by the undoped (or unintentionally doped) upper region 34b, and separated from the p-type doped first III-V compound layer 32 by the undoped (or unintentionally doped) lower region 34a. The barrier layer 36 includes a second band gap. More importantly, the second band gap of the barrier layer 36 is greater than the first band gap of the lower region 34a and the upper region 34b of the III-V compound layer 34. In some embodiments, the barrier layer 36 includes AlN, AlGaN, boron nitride (BN) or aluminum oxide (Al₂O₃). In some embodiments, the barrier layer 36 includes Alₓ₃Ga₍₁₋ₓ₃₎N, where x3 is in a range of approximately 0.3 to approximately 0.9. In some embodiments, a thickness of the barrier layer 36 is between approximately 1 nanometer (nm) and approximately 5 nm, but the disclosure is not limited thereto. In some embodiments, the barrier layer 36 is formed by an epitaxial growth such as, for example but not limited to, MOCVD or MBE.

Referring to FIG. 3B, which illustrates the semiconductor structure 100a for the HEMT device 1 or HEMT device 2 in operation in accordance with embodiments of the present disclosure. According to one or more embodiments of the present disclosure, the HEMT device 1 or the HEMT device 2 includes a heterojunction formed between two different semiconductor material layers such as the active layer 40 and the upper region 34b of the III-V compound layer 34. Electrons from a piezoelectric effect in the active layer 40 drop into the upper region 34b, and thus create a thin layer of highly mobile conducting electrons in the upper region 34b. This thin layer is referred to as a 2DEG layer 70. As shown in FIG. 3B, the 2DEG layer 70 is formed within the upper region 34b near an interface of the active layer 40 and the upper region 34b. The 2DEG layer 70 is used as a channel of the HEMT device 1 or the HEMT device 2. In some embodiments, the active layer 40 is therefore referred to as a donor-supply layer and the upper region 34b of the III-V compound layer 34 is therefore referred to as a III-V compound channel layer.

FIG. 3C is a diagram of a HEMT device 1 or 2 including the semiconductor structure 100a having the barrier layer 36 and a HEMT device without the barrier layer in accordance with embodiments of the present disclosure. Band diagram indicates electron levels versus a depth into the HEMT device 1 or the HEMT device 2. A bad gap 302 of the HEMT device 1 or the HEMT device 2 including the barrier layer 36 and a band gap 304 of a HEMT device without the barrier layer. As shown in FIG. 3C, band gap 302 indicates a discontinuity 306 due to the barrier layer 36. Such discontinuity 306 helps to reduce source-to-drain leakage. In some embodiments, the source-to-drain leakage current can be reduced be lower than 1E-8 A/μm, but the disclosure is not limited to this. In contrast, band gap 304 indicates no discontinuity, and thus source-to-drain leakage current may be higher than 1E-8 A/μm.

Referring to FIGS. 3B and 3C, it should be noted that the thickness of the upper region (the third III-V compound layer) 34b as mentioned above ranges from approximately 0.2 μm to approximately 0.4 μm in accordance with some embodiments. If the thickness of the upper region 34b is less than 0.2 μm, it is too thin to form the 2DEG layer 70. If the thickness of the upper region 34b is greater than 0.4 μm, the barrier layer 36 is too far away from the 2DEG layer 70 to provide the discontinuity 306. However, those skilled in the art should understand that the thickness range of the upper region 34b may be adjusted depending on the gate length Lg₁ or Lg₂, and/or the Al concentration in the active layer 40. Additionally, if the thickness of the lower region 34a of the III-V compound channel layer 34 is less than 0.4 μm, it is too thin that the p-type doped first III-V compound layer 32 may render adverse impact to the 2DEG layer 70.

Accordingly, the semiconductor structure 100a of the HEMT device 1 or the HEMT device 2 incorporates the barrier layer 36 between the upper region 34b and lower region 34a of the III-V compound channel layer 34 to provide the second band gap greater than the first band gap of the III-V compound channel layer 34. Accordingly, a discontinuity is created and thus punch through effect is mitigated.

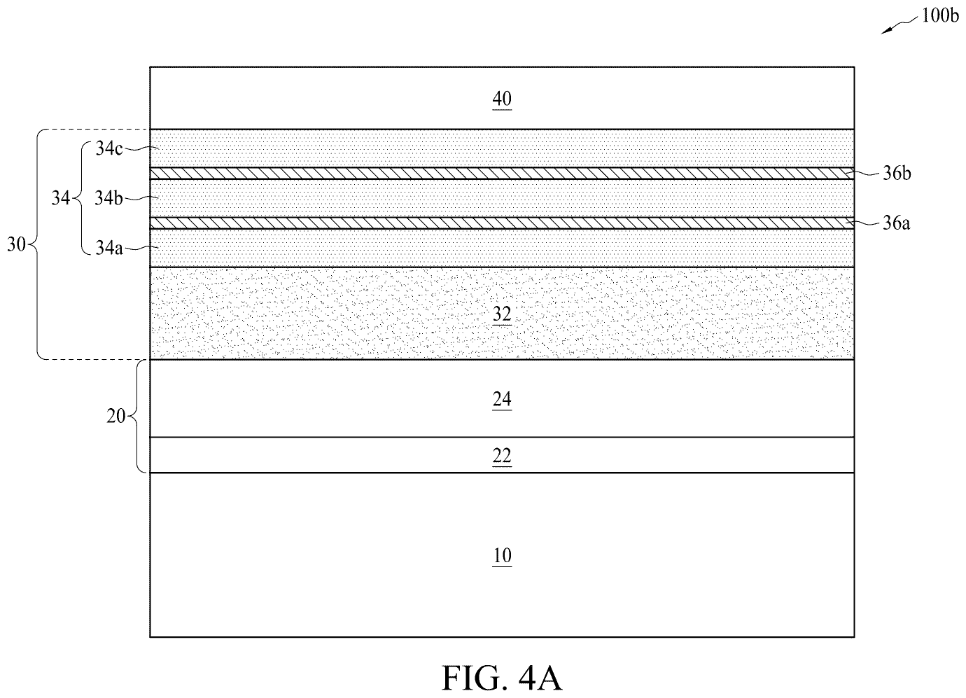

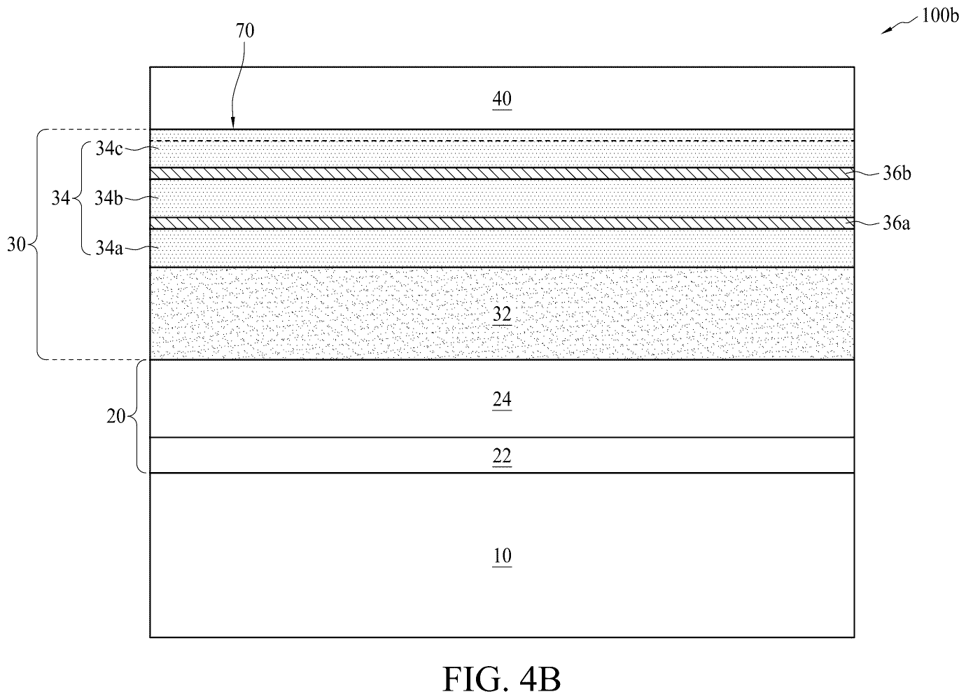

Referring to FIGS. 4A and 4B, in some embodiments, the semiconductor structure 100b is adopted in the HEMT device 1 or the HEMT device 2. The semiconductor structure 100b includes the substrate 10, the buffer layer 20 disposed over the substrate 10, the III-V compound stack disposed over the buffer layer 20, and the active layer 40 disposed over the III-V compound stack 30, as shown in FIG. 4A. It should be understood that the substrate 10, the buffer layer 20 and the active layer 40 of the semiconductor structure 100b may be similar to those layers of the semiconductor structure 100a, therefore those details are omitted in the interest of brevity.

In some embodiments, the III-V compound stack 30 of the semiconductor structure 100b is sandwiched between the buffer layer 20 and the active layer 40. The III-V compound stack 30 can include a first III-V compound layer 32. As mentioned above, the first III-V compound layer 32 can be a p-type doped III-V compound layer. In some embodiments, the p-type doped first III-V compound layer 32 of the semiconductor structure 100b is similar to the p-type doped first III-V compound layer 32 of the semiconductor structure 100a, therefore those details are omitted in the interest of brevity.

The semiconductor structure 100b includes a second III-V compound layer 34 disposed over the p-type doped first III-V compound layer 32. In other words, the second III-V compound layer 34 is sandwiched between the p-type doped first III-V compound layer 32 and the active layer 40. In some embodiments, the second III-V compound layer 34 includes at least three regions. As shown in FIGS. 4A and 4B, the second III-V compound layer 34 includes a first region 34a, a second region 34b and a third region 34c, and the second region 34b are sandwiched between the first region 34a and the third region 34c. The active layer 40 is disposed over the second III-V compound layer 34. In some embodiments, the active layer 40 is disposed on and in contact with the third region 34c of the second III-V compound layer 34. The semiconductor structure 100b further includes a first barrier layer 36a sandwiched between the first region 34a and the second region 34b. The semiconductor structure 100b further includes a second barrier layer 36b sandwiched between the second region 34b and the third region 34c.

Still referring to FIG. 4A, the first region 34a, the second region 34b and the third region 34c of the second III-V compound layer 34 can include a same material such as an undoped III-V compound layer or an unintentionally doped III-V compound layer. In some embodiments, the second region 34b and the third region 34c of the second III-V compound layer 34 can include the same material such as an undoped GaN layer or an unintentionally doped GaN layer, but the disclosure is not limited thereto. Accordingly, the first region 34a, the second region 34b and the third region 34c of the second III-V compound layer 34 include a first band gap. In some embodiments, a thickness of the first region 34a of the second III-V compound layer 34 is between approximately 0.2 μm and approximately 0.4 μm, a thickness of the second region 34b of the second III-V compound layer 34 is between approximately 0.2 μm and approximately 0.4 μm, and a thickness of the third region 34c of the second III-V compound layer 34 is between approximately 0.2 μm and approximately 0.4 μm. In some embodiments, the thicknesses of the first region 34a, the second region 34b and the third region 34c are similar to each other, but the disclosure is not limited thereto.

Still referring to FIG. 4A, the first barrier layer 36a sandwiched between the first region 34a and the second region 34b includes a second band gap, and the second barrier layer 36b sandwiched between the second region 34b and the third region 34c includes a third band gap. More importantly, both the second band gap of the first barrier layer 36a and the third band gap of the second barrier layer 36b are greater than the first band gap of the second III-V compound layer 34. In other words, both the second band gap of the first barrier layer 36a and the third band gap of the second barrier layer 36b are greater than the first band gap of the first region 34a, the second region 34b and the third region 34c. In some embodiments, the first barrier layer 36a includes AlN, AlGaN, boron nitride (BN) or aluminum oxide (Al₂O₃). In some embodiments, the first barrier layer 36a includes Alₓ₄Ga₍₁₋ₓ₄₎N, where x4 is in a range of approximately 0.3 to approximately 0.9. In some embodiments, the second barrier layer 36b includes AlN, AlGaN, boron nitride (BN) or aluminum oxide (Al₂O₃). In some embodiments, the second barrier layer 36b includes Alₓ₅Ga₍₁₋ₓ₅₎N, where x5 is in a range of approximately 0.3 to approximately 0.9. In some embodiments, the first barrier layer 36a and the second barrier layer 36b include a same material. In some embodiments, the first barrier layer 36a and the second barrier layer 36b include different materials. In some embodiments, a thickness of the first barrier layer 36a is between approximately 1 nm and approximately 5 nm, but the disclosure is not limited thereto. In some embodiments, a thickness of the second barrier layer 36b is between approximately 1 nm and approximately 5 nm, but the disclosure is not limited thereto.

Referring to FIG. 4B, which illustrates the semiconductor structure 100b for the HEMT device 1 or HEMT device 2 in operation in accordance with embodiments of the present disclosure. According to one or more embodiments of the present disclosure, the HEMT device 1 or the HEMT device 12 includes a heterojunction formed between two different semiconductor material layers such as the active layer 40 and the third region 34c of the second III-V compound layer 34. Electrons from a piezoelectric effect in the active layer 40 drop into the third region 34c of the second III-V compound layer 34, and thus create a thin layer of highly mobile conducting electrons in the third region 34b. This thin layer is referred to as a 2DEG layer 70. As shown in FIG. 4B, the 2DEG layer 70 is formed within the third region 34c of the second III-V compound layer 34 near an interface of the active layer 40 and the third region 34c of the second III-V compound layer 34. The 2DEG layer 70 is used as a channel of the HEMT device 1 or the HEMT device 2. In some embodiments, the active layer 40 is therefore referred to as a donor-supply layer and the third region 34c of the second III-V compound layer 34 is therefore referred to as a III-V compound channel layer.

As mentioned above, since the third band gap of the second barrier layer 36b is greater than the first band gap of the third region 34c of the second III-V compound layer 34, the second barrier layer 36b under the third region 34c creates a discontinuity. Such discontinuity 306 helps to reduce source-to-drain leakage. Referring to FIG. 4B, it should be noted that the thickness of the third region 34c of the second III-V compound layer 34 as mentioned above ranges from approximately 0.2 μm to approximately 0.4 μm in accordance with some embodiments. If the thickness of the third region 34c of the second III-V compound layer 34 is less than 0.2 μm, it is too thin to form the 2DEG layer 70. If the thickness of the third region 34c of the second III-V compound layer 34 is greater than 0.4 μm, the second barrier layer 36b is too far away from the 2DEG layer 70 to provide the discontinuity. However, those skilled in the art should understand that the thickness range of the third region 34c of the second III-V compound layer 34 may be adjusted depending on the gate length Lg₁ or Lg₂, and/or the Al concentration in the active layer 40. Further, it should be noted that the thickness of the second region 34b of the second III-V compound layer 34 as mentioned above ranges from approximately 0.2 μm to approximately 0.4 μm in accordance with some embodiments. That is, a distance between the first barrier layer 36a and the second barrier layer 36b ranges from approximately 0.2 μm to approximately 0.4 μm in accordance with some embodiments. If the thickness of the second region 34c (the distance between the first barrier layer 36a and the second barrier layer 36b) is less than 0.2 μm, the two barrier layers 36a and 36b may be too close to each other to create the discontinuity. In some embodiments, the two barrier layers 36a and 36b are so close that a conductive layer is formed by the two barrier layers 36a and 36b, and thus provide adverse impact to the HEMT device 1 or the HEMT device 2. Additionally, if the thickness of the first region 34a of the second III-V compound layer 34 is less than 0.4 μm, it is too thin that the p-type doped first III-V compound layer 32 may render adverse impact to the 2DEG layer 70.

Accordingly, the semiconductor structure 100b of the HEMT device 1 or the HEMT device 2 incorporates the two barrier layers 36a and 36b into the second III-V compound layers 34 to provide the second band gap and the third band gap greater than the first band gap of the second III-V compound layer 34. Accordingly, a discontinuity is created and thus punch through effect is mitigated.

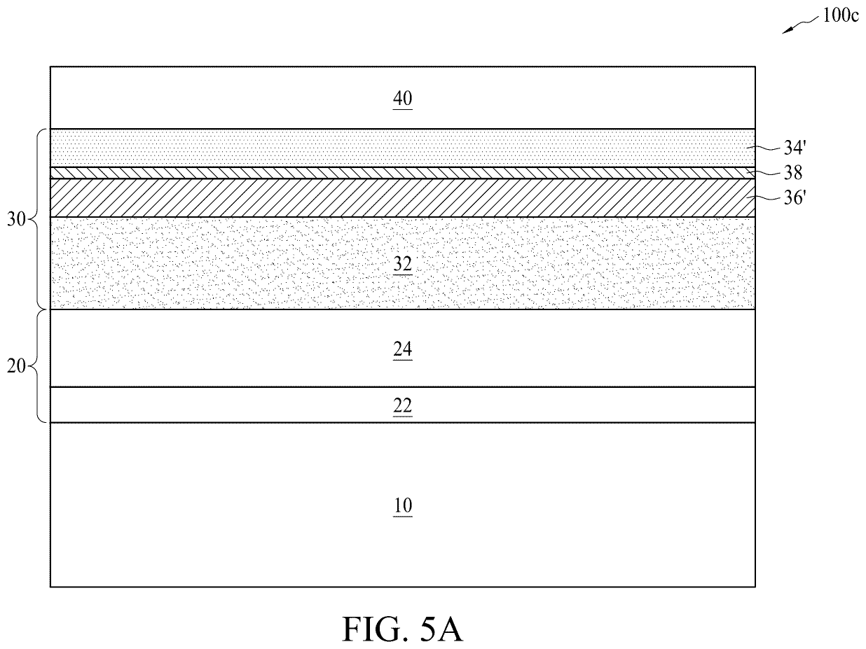

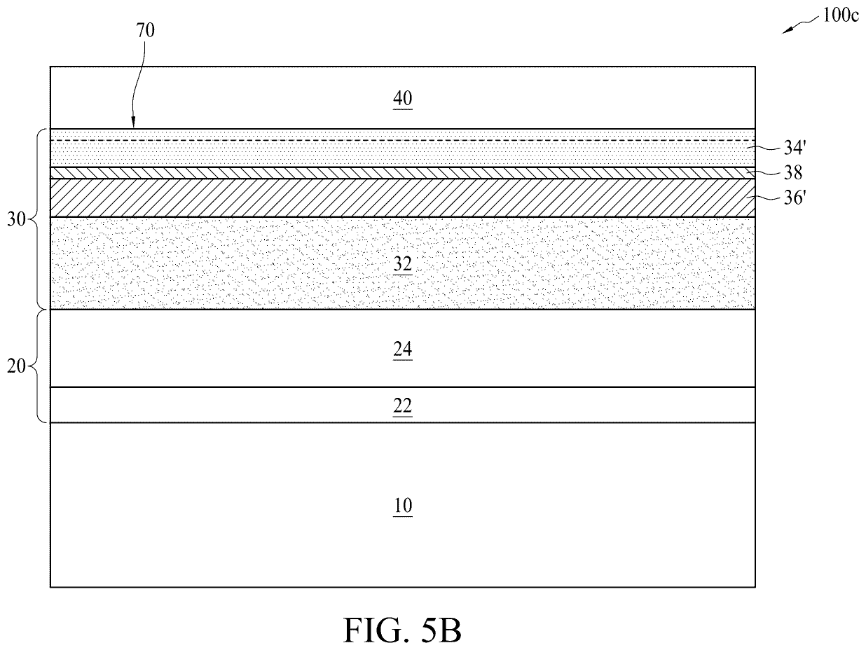

Referring to FIGS. 5A and 5B, in some embodiments, the semiconductor structure 100c is adopted in the HEMT device 1 or the HEMT device 2. The semiconductor structure 100c includes the substrate 10, the buffer layer 20 disposed over the substrate 10, the III-V compound stack 30 disposed over the buffer layer 20, and the active layer 40 disposed over the III-V compound stack 30, as shown in FIG. 5A. It should be understood that the substrate 10, the buffer layer 20 and the active layer 40 of the semiconductor structure 100c may be similar to those layers of the semiconductor structure 100a, therefore those details are omitted in the interest of brevity.

In some embodiments, the III-V compound stack 30 of the semiconductor structure 100b is sandwiched between the buffer layer 20 and the active layer 40. The III-V compound stack 30 can include a first III-V compound layer 32. As mentioned above, the first III-V compound layer 32 can be a p-type doped III-V compound layer. In some embodiments, the p-type doped first III-V compound layer 32 of the semiconductor structure 100c is similar to the p-type doped first III-V compound layer 32 of the semiconductor structure 100a, therefore those details are omitted in the interest of brevity.

Still referring to FIG. 5A, the semiconductor structure 100c includes a second III-V compound layer 34′ disposed over the p-type doped first III-V compound layer 32. In other words, the second III-V compound layer 34′ is sandwiched between the p-type first doped III-V compound layer 32 and the active layer 40. In some embodiments, the active layer 40 is disposed on and in contact with the second III-V compound layer 34′. In some embodiments, the second III-V compound layer 34′ can include an undoped III-V compound layer or an unintentionally doped III-V compound layer. In some embodiments, the second III-V compound layer 34′ can include an undoped GaN layer or an unintentionally doped GaN layer, but the disclosure is not limited thereto. Accordingly, the second III-V compound layer 34′ includes a first band gap. In some embodiments, a thickness of the second III-V compound layer 34′ is between approximately 0.2 μm and approximately 0.4 μm, but the disclosure is not limited thereto.

The semiconductor structure 100c further includes a first barrier layer 36′ disposed on the p-type doped first III-V compound layer 32 and a second barrier layer 38 disposed on the first barrier layer 36′. As shown in FIG. 5A, the first barrier layer 36′ is sandwiched between the p-type doped first III-V compound layer 32 and the undoped (or unintentionally doped) second III-V compound layer 34′ while the second barrier layer 38 is sandwiched between the first barrier layer 36′ and the undoped (or unintentionally doped) second III-V compound layer 34′. Further, the first barrier layer 36′ contacts the doped first III-V compound layer 32. Still referring to FIG. 5A, the first barrier layer 36′ includes a second band gap, and the second barrier layer 38 includes a third band gap. More importantly, both the second band gap of the first barrier layer 36′ and the third band gap of the second barrier layer 38 are greater than the first band gap of the second III-V compound layer 34′. In some embodiments, the second band gap of the first barrier layer 36′ is different from the third band gap of the second barrier layer 38. In some embodiments, the first barrier layer 36′ includes AlN, AlGaN, boron nitride (BN) or aluminum oxide (Al₂O₃). In some embodiments, the first barrier layer 36′ includes Alₓ₆Ga₍₁₋ₓ₆₎N, where x6 is in a range of approximately 0.2 to approximately 0.9. In some embodiments, the second barrier layer 38 includes AlN, AlGaN, boron nitride (BN) or aluminum oxide (Al₂O₃). In some embodiments, the second barrier layer 38 includes Alₓ₇Ga₍₁₋ₓ₇₎N, where x7 is in a range of approximately 0.3 to approximately 0.9. In some embodiments, the first barrier layer 36′ and the second barrier layer 38 include different materials. For example but not limited to, the first barrier layer 36′ includes a Al_{0.2}Ga_{0.8}N layer while the second barrier layer 38 includes a AlN layer, but the disclosure is not limited thereto. In some embodiments, a thickness of the first barrier layer 36′ is greater than a thickness of the second barrier layer 38. In some embodiments, the thickness of the first barrier layer 36′ is between approximately 15 nm and approximately 0.5 μm, but the disclosure is not limited thereto. In some embodiments, the thickness of the second barrier layer 38 is between approximately 1 nm and approximately 5 nm, but the disclosure is not limited thereto.

Referring to FIG. 5B, which illustrates the semiconductor structure 100c for the HEMT device 1 or the HEMT device 2 in operation in accordance with embodiments of the present disclosure. According to one or more embodiments of the present disclosure, the HEMT device 1 or the HEMT device 2 includes a heterojunction formed between two different semiconductor material layers such as the active layer 40 and the second III-V compound layer 34′. Electrons from a piezoelectric effect in the active layer 40 drop into the second III-V compound layer 34′, and thus create a thin layer of highly mobile conducting electrons in the second III-V compound layer 34′. This thin layer is referred to as a 2DEG layer 70. As shown in FIG. 5B, the 2DEG layer 70 is formed within the second III-V compound layer 34′ near an interface of the active layer 40 and the second III-V compound layer 34′. The 2DEG layer 70 is used as a channel of the HEMT device 1 or the HEMT device 2. In some embodiments, the active layer 40 is therefore referred to as a donor-supply layer and the second III-V compound layer 34′ is therefore referred to as a III-V compound channel layer.

As mentioned above, since the third band gap of the second barrier layer 38 is greater than the first band gap of the III-V compound channel layer 34′, the second barrier layer 38 under the III-V compound channel layer 34′ creates a discontinuity. Such discontinuity helps to reduce source-to-drain leakage. Referring to FIG. 5B, it should be noted that the thickness of the III-V compound channel layer 34′ as mentioned above ranges from approximately 0.2 μm to approximately 0.4 μm in accordance with some embodiments. If the thickness of the III-V compound channel layer 34′ is less than 0.2 μm, it is too thin to form the 2DEG layer 70. If the thickness of the III-V compound channel layer 34′ is greater than 0.4 μm, the second barrier layer 38 is too far away from the 2DEG layer 70 to provide the discontinuity. However, those skilled in the art should understand that the thickness range of the III-V compound channel layer 34′ may be adjusted depending on the gate length Lg₁ or Lg₂, and/or Al concentration in the active layer 40. Further, if the thickness of the first barrier layer 36′ is less than 15 nm, it is too thin that the p-type doped first III-V compound layer 32 may render adverse impact to the 2DEG layer 70.

Accordingly, the semiconductor structure 100c of the HEMT device 1 or the HEMT device 2 incorporates the two barrier layers 36′ and 38 between the doped first III-V compound layer 32 and the III-V compound channel layer 34′ to provide a greater band gap. Accordingly, a discontinuity is created and thus punch through effect is mitigated.

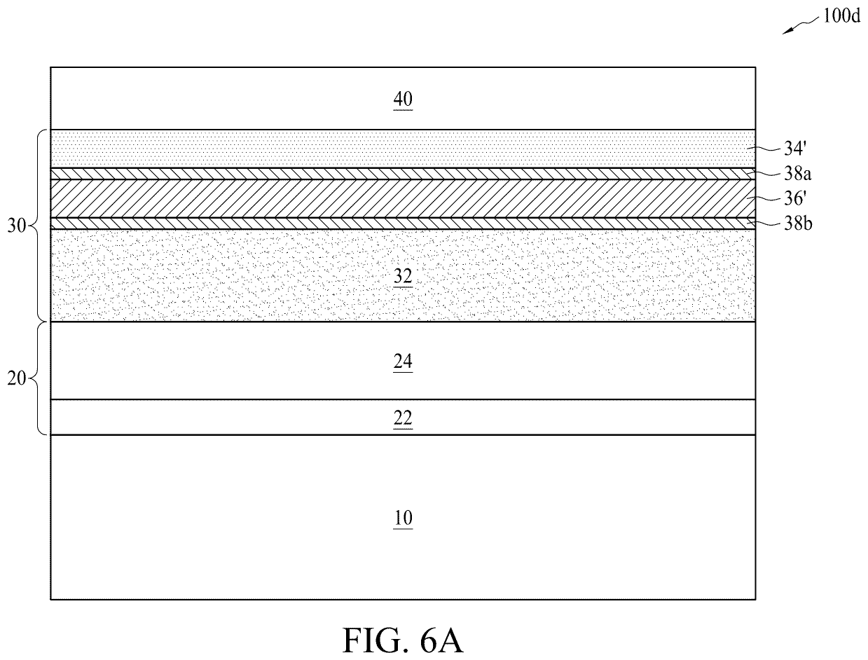

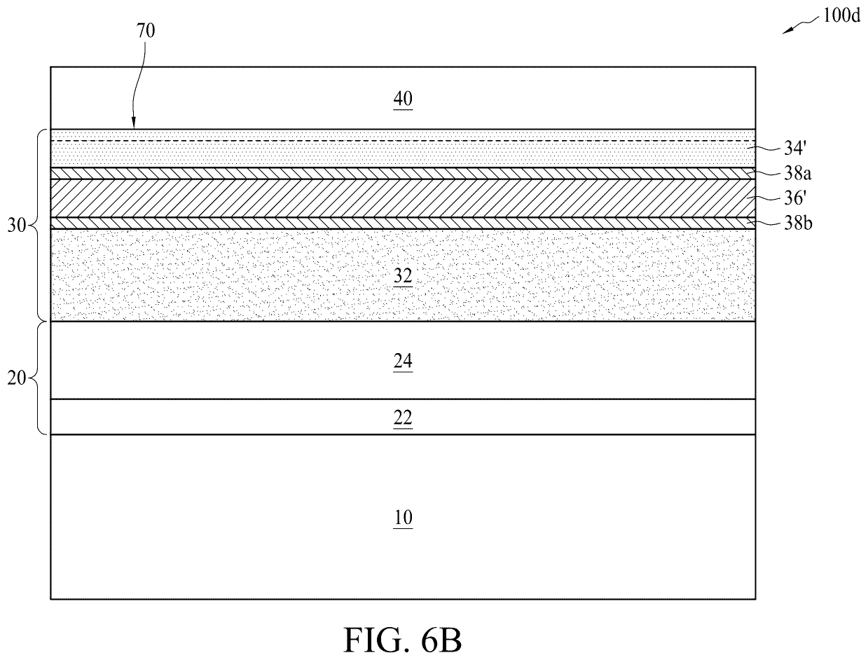

Referring to FIGS. 6A and 6B, in some embodiments, the semiconductor structure 100c is adopted in the HEMT device 1 or the HEMT device 2. The semiconductor structure 100d includes the substrate 10, the buffer layer 20 disposed over the substrate 10, the III-V compound stack 30 disposed over the buffer layer 20, and the active layer 40 disposed over the III-V compound stack 30, as shown in FIG. 6A. It should be understood that the substrate 10, the buffer layer 20 and the active layer 40 of the semiconductor structure 100d may be similar to those layers of the semiconductor structure 100a, therefore those details are omitted in the interest of brevity.

In some embodiments, the III-V compound stack 30 of the semiconductor structure 100b is sandwiched between the buffer layer 20 and the active layer 40. The III-V compound stack 30 can includes a first III-V compound layer 32. As mentioned above, the first III-V compound layer 32 can be a p-type doped III-V compound layer. In some embodiments, the p-type doped first III-V compound layer 32 of the semiconductor structure 100c is similar to the p-type doped first III-V compound layer 32 of the semiconductor structure 100a, therefore those details are omitted in the interest of brevity.

Still referring to FIG. 6A, the semiconductor structure 100d includes a second III-V compound layer 34′ disposed over the first III-V compound layer 32. In other words, the second III-V compound layer 34′ is sandwiched between the p-type doped first III-V compound layer 32 and the active layer 40. In some embodiments, the active layer 40 is disposed on and in contact with the second III-V compound layer 34′. In some embodiments, the second III-V compound layer 34′ can include an undoped III-V compound layer or an unintentionally doped III-V compound layer. In some embodiments, the second III-V compound layer 34′ can include an undoped GaN layer or an unintentionally doped GaN layer, but the disclosure is not limited thereto. Accordingly, the second III-V compound layer 34′ includes a first band gap. In some embodiments, a thickness of the second III-V compound layer 34′ is between approximately 0.2 μm and approximately 0.4 μm, but the disclosure is not limited thereto.

The semiconductor structure 100d further includes a first barrier layer 36′ on the p-type doped first III-V compound layer 32, a second barrier layer 38a on the first barrier layer 36′, and a third barrier layer 38b under the first barrier layer 36′. As shown in FIG. 6A, the first barrier layer 36′, the second barrier layer 38a and the third barrier layer 38b are sandwiched between the p-type doped first III-V compound layer 32 and the undoped (or unintentionally doped) second III-V compound layer 34′ while the first barrier layer 36′ is sandwiched between the second barrier layer 38a and the third barrier layer 38b. In some embodiments, the second barrier layer 38a is in contact with the undoped (or unintentionally doped) second III-V compound layer 34′, and the third barrier layer 38b is in contact with the p-type doped first III-V compound layer 32. Still referring to FIG. 6A, the first barrier layer 36′ includes a second band gap, and the second barrier layer 38a and the third barrier layer 38b include a third band gap. More importantly, both the second band gap of the first barrier layer 36′ and the third band gap of the second barrier layer 38a and the third barrier 38b are greater than the first band gap of the second III-V compound layer 34′. In some embodiments, the second band gap of the first barrier layer 36′ is different from the third band gap of the second barrier layer 38a and the third barrier layer 38b. In some embodiments, the first barrier layer 36′ includes AlN, AlGaN, boron nitride (BN) or aluminum oxide (Al₂O₃). In some embodiments, the first barrier layer 36′ includes Alₓ₈Ga₍₁₋ₓ₈₎N, where x8 is in a range of approximately 0.2 to approximately 0.9. In some embodiments, the second barrier layer 38a and the third barrier layer 38b include AlN, AlGaN, boron nitride (BN) or aluminum oxide (Al₂O₃). In some embodiments, the second barrier layer 36′ includes Alₓ₉Ga₍₁₋ₓ₉₎N, where x9 is in a range of approximately 0.3 to approximately 0.9. In some embodiments, the first barrier layer 36′ includes the material different from that of the second barrier layer 38a and the third barrier layer 38b. For example but not limited to, the first barrier layer 36′ includes a Al_{0.2}Ga_{0.8}N layer while the second barrier layer 38a and the third barrier layer 38b individually include a AIN layer, but the disclosure is not limited thereto. In some embodiments, the three barrier layers 36′, 38a and 38b include materials different from each other, but the disclosure is not limited thereto.

In some embodiments, a thickness of the first barrier layer 36′ is greater than a thickness of the second barrier layer 38a and the third barrier layer 38b. In some embodiments, the thickness of the second barrier layer 38a is similar to the thickness of the third barrier layer 38b, as shown in FIG. 6A. In some embodiments, the thickness of the second barrier layer 38a is different from the thickness of the third barrier layer 38b. In some embodiments, the thickness of the first barrier layer 36′ is between approximately 15 nm and approximately 0.5 μm, but the disclosure is not limited thereto. In some embodiments, the thickness of the second barrier layer 38a is between approximately 1 nm and approximately 5 nm, but the disclosure is not limited thereto. In some embodiments, the thickness of the third barrier layer 38b is between approximately 1 nm and approximately 5 nm, but the disclosure is not limited thereto.

Referring to FIG. 6B, which illustrates the semiconductor structure 100d for the HEMT device 1 or the HEMT device 2 in operation in accordance with embodiments of the present disclosure. According to one or more embodiments of the present disclosure, the HEMT device 1 or the HEMT device 2 includes a heterojunction formed between two different semiconductor material layers such as the active layer 40 and the second III-V compound layer 34′. Electrons from a piezoelectric effect in the active layer 40 drop into the second III-V compound layer 34′, and thus create a thin layer of highly mobile conducting electrons in the second III-V compound layer 34′. This thin layer is referred to as a 2DEG layer 70. As shown in FIG. 6B, the 2DEG layer 70 is formed within the second III-V compound layer 34′ near an interface of the active layer 40 and the second III-V compound layer 34′. The 2DEG layer 70 is used as a channel of the HEMT device 1 or the HEMT device 2. In some embodiments, the active layer 40 is therefore referred to as a donor-supply layer and the second III-V compound layer 34′ is therefore referred to as a III-V compound channel layer.

As mentioned above, since the third band gap of the second barrier layer 38a is greater than the first band gap of the III-V compound channel layer 34′, the second barrier layer 38a under the III-V compound channel layer 34′ creates a discontinuity. Such discontinuity helps to reduce source-to-drain leakage. Referring to FIG. 6B, it should be noted that the thickness of the III-V compound channel layer 34′ as mentioned above ranges from approximately 0.2 μm to approximately 0.4 μm in accordance with some embodiments. If the thickness of the III-V compound channel layer 34′ is less than 0.2 μm, it is too thin to form the 2DEG layer 70. If the thickness of the III-V compound channel layer 34′ is greater than 0.4 μm, the second barrier layer 38b is too far away from the 2DEG layer 70 to provide the discontinuity. However, those skilled in the art should understand that the thickness range of the III-V compound channel layer 34′ may be adjusted depending on the gate length Lg₁ or Lg₂, and/or the Al concentration in the active layer 40. Further, if the thickness of the first barrier layer 36′ is less than 15 nm and the thickness of the third barrier layer 38a is less than 1 nm, the p-type doped first III-V compound layer 32 may be too close, and thus it renders adverse impact to the 2DEG layer 70.

Accordingly, the semiconductor structure 100d of the HEMT device 1 or the HEMT device 2 incorporates a composite structure including three barrier layers 36′, 38a and 38b between the p-type doped first III-V compound layer 32 and the III-V compound channel layer 34′ to provide a greater band gap. Accordingly, a discontinuity is created and thus punch through effect is mitigated.

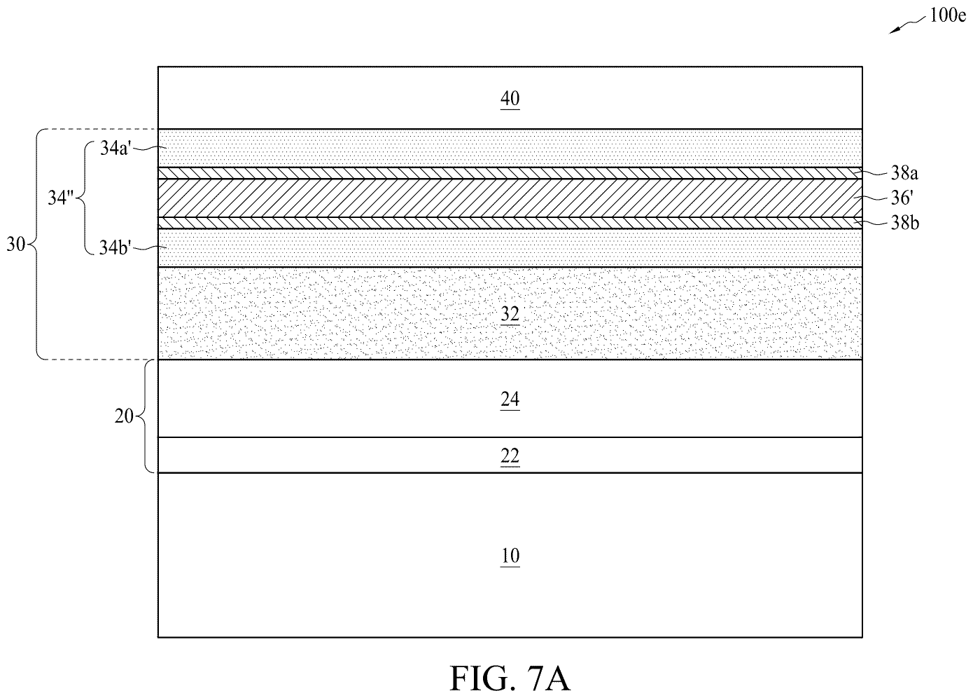

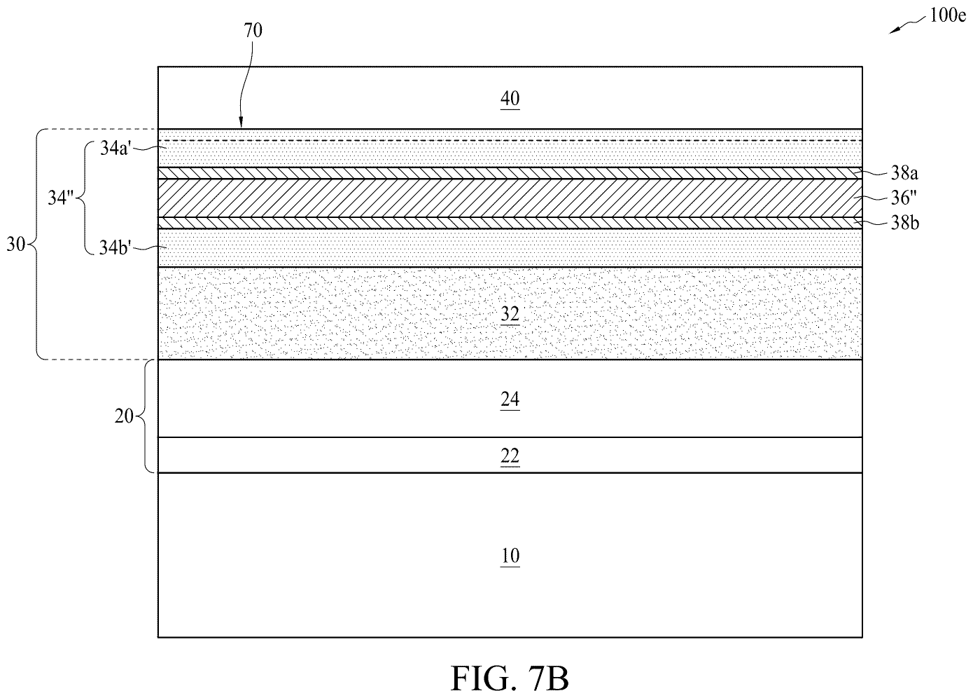

Referring to FIGS. 7A and 7B, in some embodiments, the semiconductor structure 100e is adopted in the HEMT device 1 or the HEMT device 2. The semiconductor structure 100e includes the substrate 10, the buffer layer 20 disposed over the substrate, the III-V compound stack 30 disposed over the buffer layer 20, and the active layer 40 disposed over the III-V compound stack 30, as shown in FIG. 7A. It should be understood that the substrate 10, the buffer layer 20 and the active layer 40 of the semiconductor structure 100e may be similar to those layers of the semiconductor structure 100a, therefore those details are omitted in the interest of brevity.

In some embodiments, the III-V compound stack 30 of the semiconductor structure 100b is sandwiched between the buffer layer 20 and the active layer 40. The III-V compound stack 30 can includes a first III-V compound layer 32. As mentioned above, the first III-V compound layer 32 can be a p-type doped III-V compound layer. In some embodiments, the p-type doped first III-V compound layer 32 of the semiconductor structure 100e is similar to the p-type doped first III-V compound layer 32 of the semiconductor structure 100a, therefore those details are omitted in the interest of brevity.

Still referring to FIG. 7A, the semiconductor structure 100e includes a second III-V compound layer 34a′ disposed over the p-type doped first III-V compound layer 32 and a third III-V compound layer 34b′ disposed between the second III-V compound layer 34a′ and the p-type doped first III-V compound layer 32. In some embodiments, the active layer 40 contacts the second III-V compound layer 34a′, and the third III-V compound layer 34b′ contacts the p-type doped first III-V compound layer 32. In some embodiments, the second III-V compound layer 34a′ and the third III-V compound layer 34b′ can include a same material such as an undoped III-V compound layer or an unintentionally doped III-V compound layer. In some embodiments, the second III-V compound layer 34a′ and the third III-V compound layer 34b′ can include the same material such as an undoped GaN layer or an unintentionally doped GaN layer, but the disclosure is not limited thereto. Accordingly, the second III-V compound layer 34a′ and the third III-V compound layer 34b′ can be taken as one III-V compound layer 34″ while the second III-V compound layer 34a′ is referred to as an upper region and the third III-V compound layer 34b′ is referred to as a lower region of the III-V compound layer 34″. The upper region 34a′ and the lower region 34b′ of the III-V compound layer 34″ include a first band gap. In some embodiments, a thickness of the second III-V compound layer (the upper region) 34a′ is between approximately 0.2 μm and approximately 0.4 μm, but the disclosure is not limited thereto. In some embodiments, a thickness of the third III-V compound layer (the lower region′) 34b′ is between approximately 0.2 μm and approximately 0.4 μm, but the disclosure is not limited thereto.

The semiconductor structure 100e further includes a first barrier layer 36′ disposed on the lower region 34b, a second barrier layer 38a disposed on the first barrier layer 36′, and a third barrier layer 38b under the first barrier layer 36′. As shown in FIG. 7A, the first barrier layer 36′, the second barrier layer 38a and the third barrier layer 38b are sandwiched between the undoped (or unintentionally doped) upper region 34a′ and the undoped (or unintentionally doped) lower region 34b′. Further, the first barrier layer 36′ is sandwiched between the second barrier layer 38a and the third barrier layer 38b. Further, the lower region 34b′ is sandwiched between the third barrier layer 38b and the p-type doped first III-V compound layer 32. In some embodiments, the second barrier layer 38a is in contact with the undoped (or unintentionally doped) upper region 34a′, and the third barrier layer 38b is in contact with the undoped (or unintentionally doped) lower region 34b′. Therefore in some embodiments, the third barrier layer 38b is separated from the p-type doped III-V compound layer 32 by the lower region 34b′.

Still referring to FIG. 7A, the first barrier layer 36′ includes a second band gap, and the second barrier layer 38a and the third barrier layer 38b include a third band gap. More importantly, both the second band gap of the first barrier layer 36′ and the third band gap of the second barrier layer 38a and the third barrier 38b are greater than the first band gap of the upper region 34a′ and the lower region 34b′ of the III-V compound layer 34″. In some embodiments, the second band gap of the first barrier layer 36′ is different from the third band gap of the second barrier layer 38a and the third barrier layer 38b. In some embodiments, the first barrier layer 36′ includes AlN, AlGaN, boron nitride (BN) or aluminum oxide (Al₂O₃). In some embodiments, the first barrier layer 36′ includes Alₓ₉Ga₍₁₋ₓ₉₎N, where x9 is in a range of approximately 0.2 to approximately 0.9. In some embodiments, the second barrier layer 38a and the third barrier layer 38b include AlN, AlGaN, boron nitride (BN) or aluminum oxide (Al₂O₃). In some embodiments, the second barrier layer 38a and the third barrier layer 38b include Alₓ₁₀Ga₍₁₁ₓ₁₀₎N, where x10 is in a range of approximately 0.3 to approximately 0.9. In some embodiments, the first barrier layer 36′ includes the material different from that of the second barrier layer 38a and the third barrier layer 38b. For example but not limited to, the first barrier layer 36′ includes a Al_{0.2}Ga_{0.8}N layer while the second barrier layer 38a and the third barrier layer 38b individually include a AlN layer, but the disclosure is not limited thereto. In some embodiments, the three barrier layers 36′, 38a and 38b include materials different from each other, but the disclosure is not limited thereto.

In some embodiments, a thickness of the first barrier layer 36′ is greater than a thickness of the second barrier layer 38a and the third barrier layer 38b. In some embodiments, the thickness of the second barrier layer 38a is similar to the thickness of the third barrier layer 38b, as shown in FIG. 7A. In some embodiments, the thickness of the second barrier layer 38a is different from the thickness of the third barrier layer 38b. In some embodiments, the thickness of the first barrier layer 36′ is between approximately 15 nm and approximately 0.5 μm, but the disclosure is not limited thereto. In some embodiments, the thickness of the second barrier layer 38a is between approximately 1 nm and approximately 5 nm, but the disclosure is not limited thereto. In some embodiments, the thickness of the third barrier layer 38b is between approximately 1 nm and approximately 5 nm, but the disclosure is not limited thereto.

Referring to FIG. 7B, which illustrates the semiconductor structure 100e for the HEMT device 1 or the HEMT device 2 in operation in accordance with embodiments of the present disclosure. According to one or more embodiments of the present disclosure, the HEMT device 1 or the HEMT device 2 includes a heterojunction formed between two different semiconductor material layers such as the active layer 40 and the upper region 34a′ of the III-V compound layer 34″. Electrons from a piezoelectric effect in the active layer 40 drop into the upper region 34a′, and thus create a thin layer of highly mobile conducting electrons in the upper region 34a′. This thin layer is referred to as a 2DEG layer 70. As shown in FIG. 7B, the 2DEG layer 70 is formed within the upper region 34a′ near an interface of the active layer 40 and the upper region 34a′. The 2DEG layer 70 is used as a channel of the HEMT device 1 or the HEMT device 2. In some embodiments, the active layer 40 is therefore referred to as a donor-supply layer and the second III-V compound layer 34″ is therefore referred to as a III-V compound channel layer.

As mentioned above, since the third band gap of the second barrier layer 38a is greater than the first band gap of the III-V compound channel layer 34″, the second barrier layer 38a under the upper region 34a′ creates a discontinuity. Such discontinuity helps to reduce source-to-drain leakage. Referring to FIG. 7B, it should be noted that the thickness of the upper region 34a′ as mentioned above ranges from approximately 0.2 μm to approximately 0.4 μm in accordance with some embodiments. If the thickness of the upper region 34a′ is less than 0.2 μm, it is too thin to form the 2DEG layer 70. If the thickness of the upper region 34a′ is greater than 0.4 μm, the second barrier layer 38a is too far away from the 2DEG layer 70 to provide the discontinuity. However, those skilled in the art should understand that the thickness range of the upper region 34a′ may be adjusted depending on the gate length Lg₁ or Lg₂, and/or the Al concentration in the active layer 40.

Accordingly, the semiconductor structure 100e of the HEMT device 1 or the HEMT device 2 incorporates a composite structure including three barrier layers 36′, 38a and 38b between the upper region 34a′ and the lower region 34b′ of the III-V compound channel region 34″ and to provide a greater band gap. Accordingly, a discontinuity is created and thus punch through effect is mitigated.

Accordingly, the present disclosure therefore provides a semiconductor structure 100a, 100b, 100c, 100d or 100e including a barrier layer inserted in the GaN channel layer or a composite barrier structure inserted between the GaN channel layer and the p-type doped GaN layer. The barrier layer is under the 2DEG layer and includes a band gap greater than the GaN channel layer. Consequently, the punch through effect is mitigated due to the higher electron jump barrier provided by the barrier layer. Accordingly, device performance is improved.

In some embodiments, a semiconductor structure is provided. The semiconductor structure includes a III-V compound layer, a first barrier layer, a second barrier layer, and an active layer. The III-V compound layer includes a first region, a second region, and a third region. In some embodiments, the second region is sandwiched between the first region and the third region. The first barrier layer is sandwiched between the first region and the second region, and the second barrier layer is sandwiched between the second region and the third region. The III-V compound layer includes a first band gap, the first barrier layer includes a second band gap, and the second barrier layer includes a third band gap. The second band gap and the third band gap are greater than the first band gap.

In some embodiments, a semiconductor structure is provided. The semiconductor structure includes a p-type doped III-V compound layer, a III-V compound channel layer over the p-type doped III-V compound layer, a first barrier layer sandwiched between the p-type doped III-V compound layer and the III-V compound channel layer, and a second barrier layer sandwiched between the first barrier layer and the III-V compound channel layer. The III-V compound channel layer includes a first band gap, the first barrier layer includes a second band gap, and the second barrier layer includes a third band gap. The second band gap and the third band gap are greater than the first band gap. The second band gap is different from the third band gap.

In some embodiments, a semiconductor structure is provided. The semiconductor structure includes a p-type doped III-V compound layer, a first III-V compound layer over the p-type doped III-V compound layer, and a barrier structure disposed between the p-type doped III-V compound layer and the first III-V compound layer. The barrier structure includes a first barrier layer, a second barrier layer, and a third barrier layer. The first III-V compound layer has a first band gap, the first and third barrier layers have a second band gap, and the second barrier layer has a third band gap. The second band gap and the third band are greater than the first band gap. The second band gap is different from the third band gap.

In some embodiments, a semiconductor structure is provided. The semiconductor structure includes a p-type doped III-V compound layer, a channel layer disposed over the p-type doped III-V compound layer, and a barrier structure. The channel layer includes an upper portion and a lower portion. The barrier structure is disposed between the upper portion of the channel layer and the lower portion of the channel layer. The barrier structure includes a first barrier layer, a second barrier layer and a third barrier layer. The first barrier layer is disposed between the second barrier layer and the third barrier layer. The channel layer has a first band gap, the first barrier layer has a second band gap, and the second barrier layer has a third band gap. The second band gap and the third band gap are greater than the first band gap.

In some embodiments, a semiconductor structure is provided. The semiconductor structure includes a p-type doped III-V compound layer, an active layer disposed over the p-type doped III-V compound layer, a first channel layer and a second channel layer disposed between the p-type doped III-V compound layer and the active layer. A first barrier layer, a second barrier layer and a third barrier layer disposed between the first channel layer and the second channel layer. The first barrier layer is disposed between the second barrier layer and the third barrier layer. The first channel layer has a first band gap, the first barrier layer has a second band gap, and the second barrier layer and the third barrier layer have a third band gap. The second band gap and the third band gap are greater than the first band gap.

In some embodiments, a semiconductor structure is provided. The semiconductor structure includes a p-type doped III-V compound layer, a channel layer disposed over the p-type doped III-V compound layer, and a barrier structure. The channel layer includes an upper portion and a lower portion. The barrier structure is disposed between the upper portion of the channel layer and the lower portion of the channel layer. The barrier structure includes a first barrier layer, a second barrier layer and a third barrier layer. The first barrier layer is disposed between the second barrier layer and the third barrier layer. The upper portion of the channel layer has a first thickness, the first barrier layer has a second thickness, and the second barrier layer has a third thickness. The first thickness and the second thickness are greater than the third thickness.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure comprising:
a p-type doped III-V compound layer;
a channel layer disposed over the p-type doped III-V compound layer, wherein the channel layer comprise an upper portion and a lower portion; and
a barrier structure disposed between the upper portion of the channel layer and the lower portion of the channel layer, wherein the barrier structure comprises:
a first barrier layer;
a second barrier layer; and
a third barrier layer, wherein the first barrier layer is sandwiched between the second barrier layer and the third barrier layer,
wherein the channel layer comprises a first band gap, the first barrier layer comprises a second band gap, the second barrier layer comprises a third band gap, and the second band gap and the third band gap are greater than the first band gap.

2. The semiconductor structure of claim 1, wherein the second band gap of the firs barrier layer is different from the third band gap of the second barrier layer.

3. The semiconductor structure of claim 1, wherein the first barrier layer comprises aluminum nitride (AlN), aluminum gallium nitride (AlGaN), boron nitride (BN) or aluminum oxide (AlO).

4. The semiconductor structure of claim 3, wherein AlGaN comprises a chemical formula of AlₓGa₍₁₋ₓ₎N, where x is in a range of approximately 0.2 to approximately 0.9.

5. The semiconductor structure of claim 1, wherein the second barrier layer and the third barrier layer comprise a same material.

6. The semiconductor structure of claim 5, wherein the first barrier layer comprises a material different from that of the second barrier layer and the third barrier layer.

7. The semiconductor structure of claim 1, wherein the first barrier layer, the second barrier layer and the third barrier layer comprise different materials.

8. The semiconductor structure of claim 1, wherein a thickness of the first barrier layer is greater than a thickness of the second barrier layer, and greater than a thickness of the third barrier layer.

9. The semiconductor structure of claim 8, wherein the thickness of the second barrier layer is substantially equal to the thickness of the third barrier layer.

10. The semiconductor structure of claim 8, wherein the thickness of the second barrier layer is different from the thickness of the third barrier layer.

11. A semiconductor structure comprising:
a p-type doped III-V compound layer;
an active layer disposed over the p-type doped III-V compound layer;
a first channel layer and a second channel layer disposed between the p-type doped III-V compound layer and the active layer;
a first barrier layer disposed between the first channel layer and the second channel layer;
a second barrier layer disposed between the first channel layer and the second channel layer; and
a third barrier layer disposed between the first channel layer and the second channel layer,
wherein the first barrier layer is sandwiched between the second barrier layer and the third barrier layer,
wherein the first channel layer comprises a first band gap, the first barrier layer comprises a second band gap, the second barrier layer and the third barrier layer comprise a third band gap, and the second band gap and the third band gap are greater than the first band gap.

12. The semiconductor structure of claim 11, wherein the second barrier layer is in contact with the first channel layer.

13. The semiconductor structure of claim 11, wherein the third barrier layer is in contact with the second channel layer.

14. The semiconductor structure of claim 11, wherein the second channel layer is in contact with the p-type doped III-V compound layer.

15. The semiconductor structure of claim 11, wherein the first channel layer is in contact with the active layer.

16. A semiconductor structure comprising:
a p-type doped III-V compound layer;
a channel layer over the p-type doped III-V compound layer, wherein the channel layer comprise an upper portion and a lower portion; and
a barrier structure disposed between the upper portion of the channel layer and the lower portion of the channel layer, wherein the barrier structure comprises:
a first barrier layer;
a second barrier layer; and
a third barrier layer, wherein the first barrier layer is sandwiched between the second barrier layer and the third barrier layer,
wherein the upper portion of the channel layer comprises a first thickness, the first barrier layer comprises a second thickness, the second barrier layer comprises a third thickness, and the first thickness and the second thickness are greater than the third thickness.

17. The semiconductor structure of claim 16, wherein the thickness of the second barrier layer is substantially equal to a thickness of the third barrier layer.

18. The semiconductor structure of claim 16, wherein the thickness of the second barrier layer is different from a thickness of the third barrier layer.

19. The semiconductor structure of claim 16, wherein the channel layer comprises a first band gap, the first barrier layer comprises a second band gap, the second barrier layer comprises a third band gap, and the second band gap and the third band gap is greater than the first band gap.

20. The semiconductor structure of claim 19, wherein the third barrier layer comprises the third band gap.
